(19) United States
(12) Patent Application Publication
(10) Pub. No.: US 2025/0324546 A1
(43) Pub. Date: Oct. 16, 2025

(54) COOLING CONFIGURATION FOR MEMORY DEVICE AND RELATED COMPUTER SYSTEM

(71) Applicant: Intel Corporation, Santa Clara, CA (US)

(72) Inventors: Sandeep Ahuja, Portland, OR (US); Yuehong Fan, Shanghai (CN); Qing Jiang, Shanghai (CN); Chuansheng Liu, Shanghai (CN); Xiang Que, Suzhou (CN); Yanbing Sun, Shanghai (CN); Chuanlou Wang, Shanghai (CN); Casey Winkel, Hillsboro, OR (US); Yang Yao, Shanghai (CN); Srinath Reddy Yerakondappagari, Hillsboro, OR (US); Gene Young, St. Augustine, FL (US); Ming Zhang, Shanghai (CN)

(73) Assignee: Intel Corporation, Santa Clara, CA (US)

(21) Appl. No.: 19/082,983

(22) Filed: Mar. 18, 2025

(30) Foreign Application Priority Data
Apr. 15, 2024 (CN) 202420765812.4

(51) Int. Cl. H05K 7/20; G06F 1/20

(52) U.S. Cl. CPC H05K 7/20336; G06F 1/20; H05K 7/20254; H05K 7/20263; H05K 7/2039

(57) ABSTRACT

Systems and apparatus are disclosed for cooling configuration for memory devices. An example cooling device includes a heat sink further including a longitudinal length having a left end, a right end, and a first planar orientation, a transverse height having a top, a bottom, and a second planar orientation orthogonal to the first planar orientation, and an inner side and an outer side, the outer side including at least one channel having the second planar orientation. The example cooling device also includes a first heat pipe further including a first heat pipe portion having a left end, a right end, and the second planar orientation, the first heat pipe portion seated into the at least one channel, a heat pipe transition portion coupled to the left end of the first heat pipe portion, the transition portion including a first end having the second planar orientation and a second end having the first planar orientation, and a heat dissipation portion coupled to the second end of the heat pipe transition portion.

### BACKGROUND

In today's computer and data processing fields, a large number of memory devices (sometimes referred to herein as memory modules) are used for various functions, such as computation and storage. For example, large data processing complexes such as data centers include a large number of in-line memory devices (e.g., dual in-line memory modules). These memory modules generate considerable heat when operating.

### BRIEF DESCRIPTION OF THE DRAWINGS

FIG. 1 is a schematic diagram of an example cooling device to improve thermal management of memory devices in a manner consistent with this disclosure.

FIG. 2A is a schematic diagram of an example 3-dimensional heat pipe of a cooling device to improve thermal management of memory devices in a manner consistent with this disclosure.

FIG. 2B is a schematic diagram of an example cooling device coupled to an external cooling device to improve thermal management of memory devices in a manner consistent with this disclosure.

FIG. 2C is a schematic diagram of an alternate example cooling device to improve thermal management of memory devices in a manner consistent with this disclosure.

FIG. 3A is a schematic diagram of an example cooling device, which includes heat pipe receiving channels to improve thermal management of memory devices in a manner consistent with this disclosure.

FIG. 3B is a schematic diagram of an example cooling device, which includes a convex three-dimensional profile to improve thermal management of memory devices in a manner consistent with this disclosure.

FIGS. 3C and 3D are schematic diagrams of an example elastic structures to improve thermal management of memory devices in a manner consistent with this disclosure.

FIG. 4 is an exploded schematic diagram showing example cooling devices, which include dual heat pipes having an orthogonal profile to improve thermal management of memory devices in a manner consistent with this disclosure.

FIGS. 5A and 5B are schematic diagrams of example clip assemblies to improve thermal management of memory devices in a manner consistent with this disclosure.

FIG. 6 is a table diagram showing the improvement in heat dissipation capability achieved by example cooling devices disclosed herein.

FIG. 7 is a table diagram showing example power values supported by examples disclosed herein.

FIG. 8 is a block diagram of an example processing platform including programmable circuitry structured to execute, instantiate, and/or perform the example machine readable instructions.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Throughout the present disclosure, the same reference numbers denote the same or similar elements, parts or steps.

Examples disclosed herein include a cooling device, which is sometimes referred to herein as a cooling configuration for memory module. The cooling device is used for cooling a memory board of a memory module, in which the cooling device is structured and/or otherwise configured to cool a memory board of the memory module. Example cooling devices disclosed herein include at least one heat pipe, in which the heat pipe is structured as a flat heat pipe and has at least a first heat pipe portion, which is sometimes referred to herein as a main heat dissipation portion having main heat dissipation surfaces. The example heat pipe is also structured to include a heat dissipation portion, which is sometimes referred to herein as a third heat pipe portion. The example heat dissipation portion extends away from the memory board in the memory module, and the first heat pipe portion is disposed on at least one side of the board surfaces of the memory board. Example main heat dissipation surfaces of the first heat pipe portion are parallel to the at least one side of the surfaces of the memory board, and the main heat dissipation surfaces of the third heat pipe portion are positioned non-coplanar and non-parallel to the main heat dissipation surfaces of the first heat pipe portion, in which at least one main heat dissipation surface of the third heat pipe portion is structured to contact an external cooling device directly or via a thermal interface material (TIM).

As used herein, an “inside” or “inner direction” corresponds to a side or direction of a board (e.g., a memory board/device, a PCB, etc.) facing a memory module (e.g., an in-line memory module, such as a DIMM), and an “outer direction” refers to a side or direction opposite to the inside direction. As used herein, a “longitudinal direction” corresponds to a longitudinal or length extension direction of a surface of the board (e.g., a memory board) of a memory module (e.g., an in-line memory module), and the “transverse direction” corresponds to the transverse or width extension direction of the surface of the board of a memory module (e.g., an in-line memory module), in which the longitudinal direction is perpendicular to the transverse direction. As used herein, a “thickness direction” corresponds to a direction perpendicular to the longitudinal direction and the transverse direction of a memory module such as an in-line memory module. As used herein, a plane parallel to the plane where the longitudinal direction and the transverse direction of a memory module (e.g., an in-line memory module) are located is referred to herein as a “board plane”.

As used herein, a memory module, such as an in-line memory module, is a non-limiting example of a memory structure.

Example cooling configurations (cooling devices) disclosed herein further include a heat sink, in which the heat sink is structured in a plate-like structure and to be arranged between the memory board and the heat pipe. An inner side of the heat sink is structured to face the memory board, and structured to be parallel to the board surfaces of the memory board so as to be in full face-to-face contact with at least one side of the memory board. The example heat sink is structured to receive at least a part of the first heat pipe portion of the heat pipe on an outer side, and the main heat dissipation surfaces of the first heat pipe portion are parallel to the outer side surface of the heat sink.

The example heat sink further includes a heat sink block extending away from the heat sink at (at least) one end thereof in a longitudinal direction. The example heat sink also includes one main heat dissipation surface of the third heat pipe portion being structured to contact the external cooling device directly or via a TIM, and the heat sink block being structured to contact and cover at least another main heat dissipation surface of the third heat pipe portion.

Example cooling configurations disclosed herein include two heat pipes, each of which includes one first heat pipe portion and one third heat pipe portion. The example third heat pipe portions of the two heat pipes respectively extend away from the heat sink in opposite directions in the longitudinal direction so that the corresponding third heat pipe portions of the two heat pipes can be covered and contacted by the corresponding heat sink blocks on the other main heat dissipation surface thereof at each end of the heat sink.

Example cooling configurations (cooling devices) are structured to include and/or otherwise exhibit at least one of the following features:
the heat pipe further including at least one second transition portion structured to connect (e.g., connect physically and thermally) the first heat pipe portion and the corresponding third heat pipe portion;
the heat sink being provided with a heat pipe receiving groove or channel to receive the entire first heat pipe portion of the corresponding heat pipe therein;
the two heat pipe portions being structured to have the same or different sizes or shapes; or
the one main heat dissipation surface of the respective third heat pipe portions of the two heat pipes being structured as a flat surface or a convex-shaped surface.

In some examples, each of the two heat pipes includes one first heat pipe portion and two third heat pipe portions, so that each heat pipe includes one third heat pipe portion on either side of the heat sink in the longitudinal direction and the two corresponding third heat pipe portions of the two heat pipes on the same side of the heat sink are arranged in parallel and in contact with each other in a shape-matched manner along a thickness direction of the memory module.

In some examples, a TIM is arranged between at least one side of the memory board and the cooling configuration, and the TIM is structured as a cured TIM to be positioned between the cooling configuration and the memory board and to be pre-coated and attached to a corresponding surface of the memory module.

In some examples, each of the at least one heat pipes includes one first heat pipe portion and two third heat pipe portions, so that each heat pipe includes one third heat pipe portion to be positioned on either side of the memory board in the longitudinal direction, and the corresponding first heat pipe portion of the at least one heat pipe is structured to cover at least one entire side of the board surfaces of the memory board.

In some examples, the main heat dissipation surfaces of the third heat pipe portion are orthogonal to the main heat dissipation surface of the first heat pipe portion and are structured to be parallel to a plane where a longitudinal direction and a thickness direction of the memory board are located.

Examples disclosed herein also relate to a computer system, including: a processor; a memory or memory module; and a memory module cooling system, the memory module cooling system including: a cooling configuration device as mentioned above, the cooling configuration device being contacted and attached to the memory board via a TIM; and an external cooling device structured to be disposed on an outer surface of a memory module mainboard receiving the memory module, so that when the memory board provided with the cooling configuration device is attached to the memory module mainboard, at least one main heat dissipation surface of the third heat pipe portion of the heat pipe of the cooling configuration contacts the external cooling device directly or via a TIM.

With the cooling configuration device of the present disclosure, improved (e.g., higher) heat dissipation efficiency can be provided, improved (e.g., higher) heat dissipation requirements can be met, and improved contact between the memory board of the memory module and the cooling configuration can be ensured to meet the increasing heat dissipation requirements.

In data centers, the spacing of dual in-line memory modules (DIMMs) may be 0.3 inches or lower. One or more memory modules (devices) may be component parts of a memory board, in which the memory board includes any number of memory modules. In some examples, the memory board is a printed circuit board (PCB) on which memory modules are attached and/or otherwise mounted (e.g., soldered). In the circumstances where the power of DIMMs is increasing, heat dissipation and cooling problems caused by DIMMs are particularly prominent.

In some examples, a memory board (e.g., a printed circuit board (PCB) and/or components (e.g., surface components) disposed on the PCB) in a memory module is connected to a heat sink via a thermal interface material (TIM). In some examples, the heat sink includes a two-dimensional (2D) heat pipe and uses this 2D heat pipe to carry heat generated by the memory board and to dissipate heat from the memory module by contact with an external cooling device, such as a water cooling device.

In some examples, heat dissipation structures with 2D heat pipes used for cooling memory modules has an upper limit of heat dissipation efficiency. In some examples, heat dissipation structures generally support heat dissipation values of 28 W. Some heat dissipation structures are configured to be formed by the heat sink and a protective cover cooperating to clamp the 2D heat pipe therein. In such examples, the 2D heat pipe is required to contact a heat dissipation end connected to the heat sink and dissipate the heat to the external cooling device via the heat dissipation end (this is because the 2D heat pipe cannot dissipate heat by directly contacting the external cooling device in this specific scenario). As such, the heat dissipation efficiency is reduced and/or otherwise one or more heat dissipation requirements cannot be met at relatively small DIMM spacings (e.g., there is an upper limit to heat dissipation).

Furthermore, the TIM generally needs to have a thickness of about 0.5 mm to ensure that all surface components of the memory board of the memory module can be covered to ensure heat transfer. However, because conventional TIMs are inserted between the heat sink and the memory board during assembly, it is difficult to ensure uniform heat dissipation of the memory module. Even if a uniform TIM arrangement is achieved, in the event of an improper or non-uniform pressing force, some surface components may not be covered, resulting in uneven heat dissipation and/or lack of heat dissipation performance targets/expectations.

Examples disclosed herein include a cooling device for memory modules (e.g., DIMMs) that provide relatively higher heat dissipation efficiency when compared to known techniques and structures. Examples disclosed herein meet and/or otherwise satisfy heat dissipation requirements (e.g., heat dissipation target values measured in watts), and improve contact between a memory board (e.g., a PCB) of the memory module and the heat sink and/or improved coverage of the surface components of the memory board to meet the growing heat dissipation requirements.

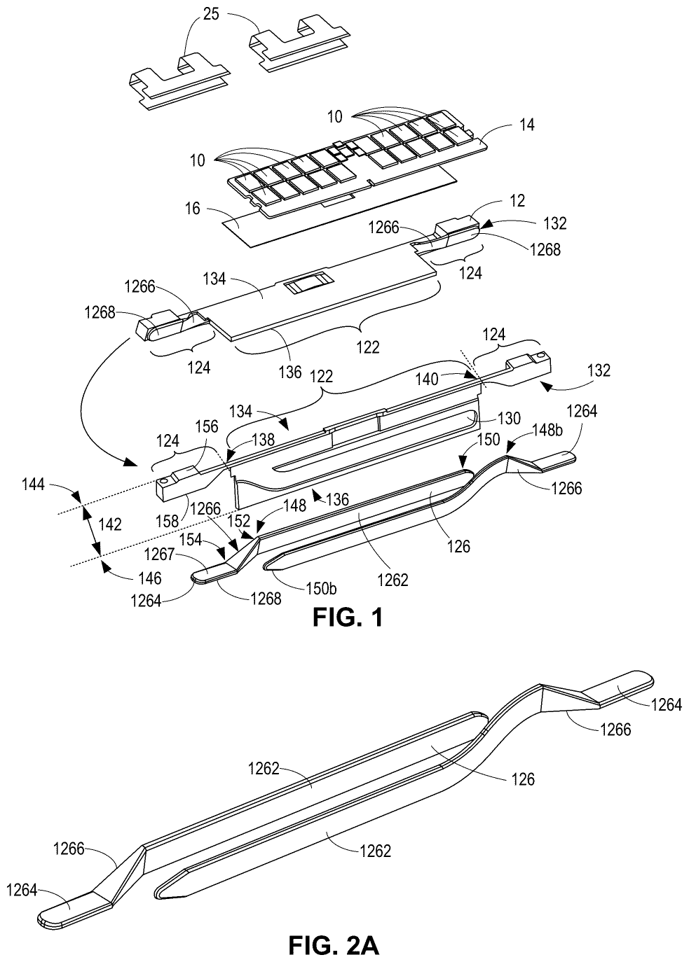

FIG. 1 shows a schematic diagram of a cooling device 12 (sometimes referred to herein as a configuration for memory module 12) according to a first example of the present disclosure. The example cooling device 12 is applied to memory modules, such as in-line memory modules. The illustrated example of FIG. 1 includes memory modules 10 (e.g., dual in-line memory modules DIMM 10), which are mounted on and/or otherwise supported by a memory board 14. Therefore, in the following description, the cooling device 12 will be described in connection with the example DIMM 10, but example cooling configurations 12 are not limited to DIMMs and are applicable to the cooling of other types of memory devices. Example cooling configurations described for the example DIMM 10 can also be applied to any other structure that needs to cool a module, including a PCB, without limitation. Stated differently, the example cooling device 12 of FIG. 1 may be referred to as a “PCB cooling configuration” without departing from the scope of the present disclosure.

In the illustrated example of FIG. 1, the cooling device 12 includes a heat sink 122 and one or more heat pipes 126. In the illustrated example of FIG. 1, the one or more heat pipes 126 include a rectangular cross section, but examples disclosed herein are not limited thereto. The example heat sink 122 of FIG. 1 includes a longitudinal length defined by a left end 138, a right end 140, and a first planar orientation. The example heat sink 122 of FIG. 1 also includes a transverse height 142 defined by a top end 144, a bottom end 146, and a second planar orientation that is orthogonal to the first planar orientation. The example heat sink 122 of FIG. 1 also includes an inner side 134 and an oppositely located outer side 136. In the illustrated example of FIG. 1, the heat sink 122 is structured to receive at least a portion of the heat pipe 126 on its outer side 136. The heat sink 122 is structured to be substantially flat and faces the memory board 14 of the memory module 10 with its inner side 134, and its inner side surface is substantially parallel to the board plane of the memory board 14 of the memory module 10. The example heat sink 122 of FIG. 1 can be in full face-to-face-contact (e.g., thermally connected) with at least one side of the memory board 14 to help conduct heat generated by the memory module(s) 10 of the memory board 14. In other words, the example heat sink 122 is structured to be disposed between the example memory board 14 and the example heat pipe 126. The inner side 134 of the heat sink 122 faces the memory board 14, and is structured to be parallel to the surface of the memory board 14 to facilitate full face-to-face contact with at least one side of the memory board 14.

The example heat pipe 126 of FIG. 1 is structured as a flat heat pipe and includes a first heat pipe portion 1262 (also referred to herein as a heat pipe body or a heat receiving portion). The first heat pipe portion 1262 of FIG. 1 includes a left end 148 and a right end 150, in which the first heat pipe portion 1262 aligns with the second planar orientation. Stated differently, the first heat pipe portion 1262 includes a longitudinal portion between the left end 148 and the right end 150. The longitudinal portion includes a first length along a first plane orientation. However, because examples disclosed herein may include one or more heat pipes 126, in the event of a second heat pipe the left end and right end orientation may be flipped to reveal a left end 150b and right end 148b.

The example heat pipe 126 includes a transition portion 1266 (also referred to as a second transition portion or a second heat pipe portion), and a heat dissipation portion 1264 (also referred to as a third heat pipe portion). In the illustrated example of FIG. 1, the transition portion 1266 includes a first end 152 that aligns with the second planar orientation, and a second end 154 that aligns with the first planar orientation. Stated differently, the transition portion 1266 “twists” and/or otherwise transforms an orientation along a length of the heat pipe 126. The second end 154 of the transition portion 1266 is coupled to (e.g., physically and thermally) the heat dissipation portion 1264.

In some examples, the heat pipe 126 is a flat heat pipe, in which the thickness of the heat pipe 126 is relatively smaller than the length and width of the heat pipe 126 and presents a flat shape (e.g., a flat strip shape). In some examples, a flat heat pipe includes a flat plane or surface corresponding to a plane or surface defined by the length and width or the flat surface of the heat pipe 126 or a portion thereof. In some examples, a flat heat pipe or its respective heat pipe portions (e.g., the heat dissipation portion 1264) include a thickness that is relatively small when compared to non-flattened portions of the heat pipe 126, for which a corresponding heat dissipation capacity in the lateral direction is relatively low and thus mainly relies on the corresponding flat surface of the heat pipe or the heat pipe portions to (a) dissipate heat (such as the heat dissipation portion 1264 of the heat pipe) or (b) receive heat (such as the heat receiving portion 1262 of the heat pipe). In some examples, the flat surface or plane of the example heat pipe 126 is also referred to as the main heat dissipation surface.

The main heat dissipation surface of the example first heat pipe portion 1262 of the example heat pipe 126 is substantially parallel to the outer surface 136 of the example heat sink 122 and is at least partially or completely received in the outer surface 136 of the heat sink 122 so that the first heat pipe portion 1262 can fully contact the outer surface 136 of the heat sink 122. Stated differently, the outer surface 136 includes at least one channel (or groove) 130 having the second planar orientation. In some examples, the heat sink 122 is structured to receive at least a portion of the first heat pipe portion 1262 of the heat pipe 126 on its outer side, in which the main heat dissipation surface of the first heat pipe portion 1262 is parallel to the outer surface of the heat sink 122. In some examples, the first heat pipe portion 1262 is a heat receiving portion of the heat pipe 126. In the illustrated example of FIG. 1, the main heat dissipation surface of the third heat pipe portion 1264 of the heat pipe 126 is not parallel to the main heat dissipation surface of the first heat pipe portion 1262 (e.g., neither parallel nor coplanar). Instead, the main heat dissipation surface of the third heat pipe portion 1264 of the heat pipe 126 is oriented substantially orthogonal to the main heat dissipation surface of the first heat pipe portion 1262, and is substantially perpendicular to the transverse direction of the memory board 14. In the illustrated example of FIG. 1, the heat pipe 126 exhibits a changed main heat dissipation surface direction/orientation, and the main heat dissipation direction is also changed due to the change in the direction of the main heat dissipation surface of different heat pipe portions. In such circumstances, the heat pipe is referred to herein as a three dimensional (3D) heat pipe because it has a three-dimensional heat dissipation direction/structure. In the illustrated example of FIG. 1, the third heat pipe portion 1264 dissipates and/or otherwise loses the heat received by the first heat pipe portion 1262, and thus represents at least one heat dissipation portion of the heat pipe 126.

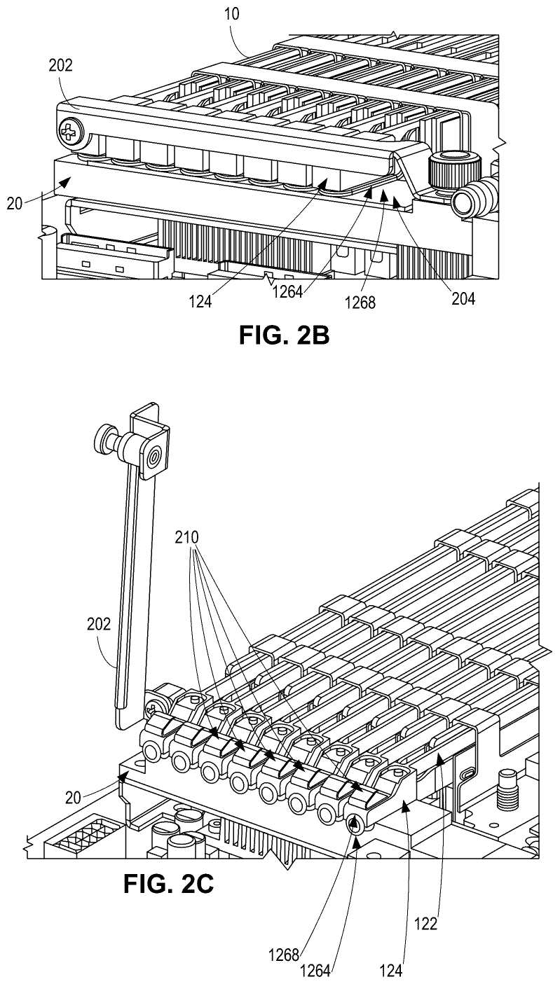

The example transition portion 1266 of the heat pipe 126 is structured to connect the first heat pipe portion 1262 and the third heat pipe portion 1264. Further, the example second transition portion 1266 and the example third heat pipe portion 1264 both extend away from the example heat sink 122 without contacting the outside of the heat sink 122. Additionally, the second transition portion 1266 and the third heat pipe portion 1264 extend away from the memory board 14 without making contact thereto. The example third heat pipe portion 1264 of FIG. 1 is substantially orthogonal to the main heat dissipation surface of the first heat pipe portion 1262. In particular, the third heat pipe portion 1264 has a first main heat dissipation surface 1267 in the transverse direction along the memory board 14, which corresponds to the side away from the electrical terminal pins of the memory board 14. The third heat pipe portion 1264 also has a second main heat dissipation surface 1268, which is opposite to the first main heat dissipation surface 1267 and closer to the electrical terminal pins of the memory board 14. In some examples, at least one of the first or second main heat dissipation surfaces of the third heat pipe portion 1264 of the heat pipe 126 can be configured to contact an external cooling device (described below in connection with FIG. 2B) to achieve the dissipation of the heat received by the first heat pipe portion 1262 of the heat pipe 126.

In some examples, the cooling device 12 further includes at least one heat sink block 124 extending away from the heat sink 122 at (at least) one end thereof in the longitudinal direction. In some examples, one of the first main heat sink surface 1267 and the second main heat sink surface 1268 of the third heat pipe portion 1264 of the heat pipe 126 is structured to contact an external cooling device. In some examples, the heat sink block 124 is structured to at least contact and cover the other main heat sink surface (e.g., an opposite side) of the third heat pipe portion 1264, so that the heat sink block 124 helps to dissipate heat from the third heat pipe portion 1264. In the illustrated example of FIG. 1, a first heat sink block 124 is coupled to the left end 138 of the heat sink 122, and a second heat sink block 124 is coupled to the right end 140 of the heat sink 122. The example heat sink block(s) 124 of FIG. 1 include a top side 156 and a bottom side 158. In some examples, the bottom side 158 of the heat sink block 124 includes a block receiving groove to thermally and/or physically couple with the first main heat dissipation surface 1267 of the heat pipe 126. In the illustrated example of FIG. 1, the heat sink block 124 also helps to cooperate with the external cooling device to clamp the cooling configuration for memory module 12.

In the illustrated example of FIG. 1, the cooling configuration 12 includes two heat pipes 126, which are independent of each other and substantially facing opposite directions. The two example heat pipes 126 each include the first heat pipe portion 1262, the second transition portion 1266, and the third heat pipe portion 1264, in which the corresponding third heat pipe portions 1264 of the two heat pipes 126 extend away from the heat sink 122 and/or the memory board 14 in opposite directions in the longitudinal direction of the memory board 14 so that the corresponding third heat pipe portions 1264 of the two heat pipes 126 can be covered and contacted on other heat dissipation surface(s) or cooling devices on either side of the heat sink 122. In this example, the first heat pipe portion 1262 is completely received, contacting, and/or otherwise thermally coupled to the heat sink 122 via one or more channels 130.

In the illustrated example of FIG. 1, the heat sink 122 is provided with at least one heat pipe receiving channel 130 (e.g., groove) to completely receive the first heat pipe portion 1262 of the corresponding heat pipe 126 so as to ensure contact between the first heat pipe portion 1262 and the heat sink 122. The example heat pipe receiving groove also saves and/or otherwise reduces a thickness of the cooling configuration for memory module 12 to achieve a relatively greater degree of compactness or space efficiency. In some examples, the heat sink block 124 includes a block receiving groove 132 on the side thereof facing the corresponding third heat pipe portion 1264 of the heat pipe 126 to ensure contact between the heat sink block 124 and the third heat pipe portion 1264, which reduces an overall height dimension of the cooling configuration memory module 12.

In the illustrated example of FIG. 1, the corresponding first heat pipe portions 1262 of the two heat pipes 126 are respectively fixedly connected to the heat sink 122 by, for example, welding, to ensure the stability between the heat pipe 126 and the heat sink 122. Of course, such welding fixation is described for purposes of example and not limitation. Examples disclosed herein may include any other suitable ways to achieve the fixation of the heat pipe 126 to the heat sink 122, such as, but not limited to adhesive connection, snap-fit connection, additional covers, a molded part, a uniform machined part, etc. In some examples, the heat sink block 124 can also be structured to be fixedly connected to the other main heat dissipation surface or the first main heat dissipation surface of the corresponding third heat pipe portion 1264 of the heat pipe 126 by any possible techniques as described above to promote the heat transfer from the third heat pipe portion 1264 to the heat sink block 124.

In the illustrated example of FIG. 1, the corresponding third heat pipe portions 1264 of the two heat pipes 126 are structured to have the same size and shape, that is, the two third heat pipe portions 1264 have the same length and width, and the shapes of the main heat dissipation surfaces of the two third heat pipe portions 1264 are also the same. In some examples, each heat sink block 124 also has substantially the same size.

In some examples, the corresponding third heat pipe portions 1264 of the two heat pipes 126 extend from the heat sink 122 or the memory board 14 at the same distance from the electrical terminal pins of the memory board 14 on both sides in the longitudinal direction of the memory board 14. In such examples, because the corresponding third heat pipe portions 1264 of the two heat pipes 126 have the same size and shape, and because the extension position from the heat sink 122 or the memory board 14 is also located at the same distance from the electrical terminal pins of the memory board 14, this structure can also be referred to as a symmetrical heat pipe structure (e.g., a symmetrical heat pipe configuration). In some examples, the extension position of the corresponding third heat pipe portions 1264 of the two heat pipes from the heat sink 122 or the memory board 14 is located at different distances from the electrical terminal pins of the memory board 14 without departing from the scope of the present disclosure.

In some examples, for the same heat pipe 126, the corresponding first heat pipe portion 1262 and the corresponding third heat pipe portion 1264 may have the same or different lengths and the same or different widths.

In some examples shown in FIG. 1, the heat sink 122 includes an opening (e.g., the receiving groove 132) in at least a portion of the area where it contacts the corresponding third heat pipe portion 1264 of the heat pipe 126 to receive the surface components of the memory board 14 that may have a higher thickness to further save space. In some examples, the memory board 14 has a certain number of surface components, such as those arranged on both sides of the memory board 14, which are capable of generating heat. In some examples, surface components have relatively larger heights compared to other components. In such examples, one or more openings on the heat sink are beneficial to accommodate these particularly high (e.g., tall) surface components. In some examples, although the compactness is only improved by about the thickness of the heat sink, this is beneficial for a device in which multiple memory boards are arranged in parallel, and it will eventually accumulate considerable space savings, so that more memory modules can be arranged in a limited/finite space. In some examples, the corresponding third heat pipe portion of the 3D heat pipe directly contacts the relatively higher thickness surface components in the memory board 14 to achieve cooling and heat dissipation of surface components.

In the illustrated example of FIG. 1, without taking into account the relatively higher thickness surface components in the memory module 10 as described above, to ensure that other surface components of the memory module 10 are in contact with the inner surface of the heat sink 122, and to transfer heat to the heat sink 122 as much as possible, a thermal interface material (TIM) 16 is provided between the memory board 14 and the inner surface of the heat sink 122 so that the surface elements of the memory module 10 can transfer heat via the TIM 16 to ensure sufficient cooling and heat dissipation of these surface elements and the memory board 14.

In the illustrated example of FIG. 1, the cooling configuration for memory module 12 can be kept relatively fixed with respect to the memory board 14 by an appropriate structure. For example, FIG. 1 shows clamps 25 that enable the cooling configuration for memory module 12 and the memory board 14 to be clamped and held together, so that the memory board 14 provided with the cooling configuration memory module 12 can be subsequently installed on, for example, a memory module mainboard. Of course, such a clamping fixture is described for purposes of example and not limitation, and any other appropriate fixing structure(s) to keep the cooling configuration and the memory board relatively fixed (e.g., such as snap connections, hook connections, bonding and other techniques) may be considered without departing from the scope of the present disclosure. In fact, these fixing structure(s) and/or technique(s) can be adjusted or replaced with each other or used in combination according to actual conditions.

Although not shown in the illustrated example of FIG. 1, the second main heat dissipation surface 1268 of the third heat pipe portion 1264 of the heat pipe 126 is structured to contact the heat dissipation surface of an external cooling device so as to further enhance the heat dissipation effect of the cooling configuration for memory module 12 with the help of the external cooling device. This will be described in detail below, but it should be understood that examples disclosed herein can be appropriately applied to the example of FIG. 1, even if the example of FIG. 1 is not described in detail there.

FIG. 2A is a schematic diagram of example three-dimensional a heat pipes 126 of a cooling device 12 according to a second example of the present disclosure. FIG. 2B shows a schematic diagram of coupling the cooling configuration for memory module 12 to an external cooling device 20 according to the second example of the present disclosure.

In the illustrated example of FIG. 2A, the construction of the heat pipe 126 of the cooling device 12 is substantially the same as the construction of the heat pipe 126 in the illustrated example of FIG. 1, and the only difference is the size of the corresponding third heat pipe portion 1264 of the two heat pipes 126. As described above, in the illustrated example of FIG. 1, the corresponding third heat pipe portions 1264 of the two heat pipes 126 are structured to have the same size and shape, that is, the two third heat pipe portions 1264 have the same length and the same width. However, the illustrated example of FIG. 2B shows a schematic diagram of the coupling of the cooling configuration for memory module 12 to the external cooling device 20 according to the second example of the present disclosure. Generally, to increase (e.g., maximize) the heat dissipation capacity of the heat pipe 126, the third heat pipe portion 1264 contacts the external cooling device 20 as much as possible. In the illustrated example of FIG. 2B, for the external cooling device 20 disposed on one side of the memory module mainboard has a clamp 202 for fixing and/or otherwise securing the installed memory module 10 (which includes the cooling configuration for memory module 12). In particular, the heat dissipation surface of the external cooling device 20 on this side cannot be fully used to contact the entire second main heat dissipation surface 1268 of the corresponding third heat pipe portion 1264 of the corresponding heat pipe 126. For example, in the illustrated example of FIG. 2B, on one side of the external cooling device 20, the size of the portion that can be used to contact the second main heat dissipation surface of the corresponding third heat pipe portion 1264 changes from 20 mm to 15 mm. In this case, the excessive length of the third heat pipe portion 1264 will cause a conflict with the clamp 202 disposed on the external cooling device 20. Therefore, for this case, some examples disclosed herein adjust the length of the corresponding third heat pipe portion 1264 of the heat pipe 126 on this side to 15 mm. For circumstances where the external cooling device 20 is not provided with a clamp 202 for fixing the installed memory module 10 (which includes the cooling configuration for memory module 12), it is not necessary to shorten the length of the corresponding third heat pipe portion 1264 to ensure the heat dissipation performance. In this case, because the length of the third heat pipe portion 1264 is shortened on one side to accommodate the corresponding external cooling device 20, the length of the third heat pipe portion 1264 on the other side is different in size, which is also called an asymmetric structure.

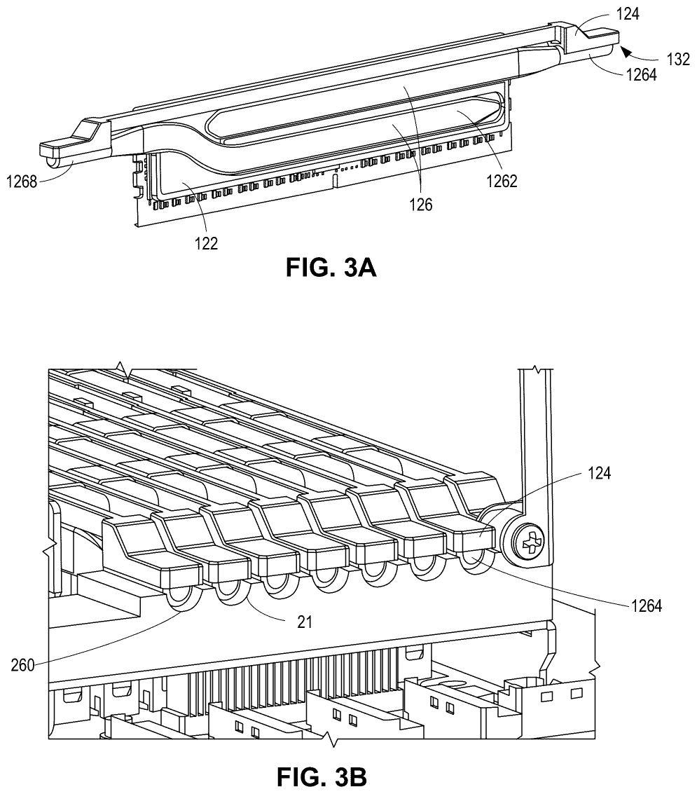

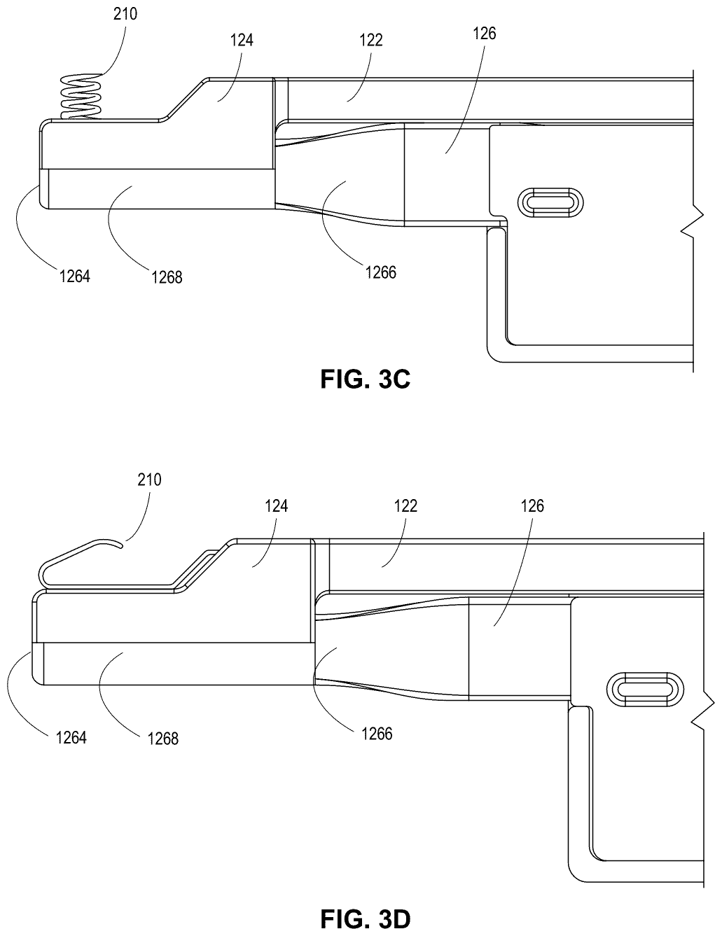

FIG. 2C is a schematic diagram of an alternate example cooling device having the clamp 202 in an open position. The illustrated example of FIG. 2C includes the external cooling device 20 coupled to any number of second main heat dissipation surfaces 1268 of corresponding third heat pipe portions 1264. Additionally, the third heat pipe portions 1264 are coupled to respective heat sink blocks 124. To maintain a coupling force on the heat sink blocks 124, and the heat dissipation surfaces 1268 with the external cooling device, the illustrated example of FIG. 2C includes elastic structures 210. When the example clamp 202 is moved to a closed position, the elastic structures 210 exhibit a force (e.g., a contact force) between the closed clamp 202 and all structures beneath it, thereby enabling improved thermal connectivity. While the example elastic structures 210 of the illustrated example of FIG. 2C are shown as clips (e.g., metallic clips), examples disclosed herein are not limited thereto, as described in further detail below in connection with FIGS. 3C and 3D.

In some examples an additional TIM 204 is disposed between the second main heat dissipation surface of the corresponding third heat pipe portion 1264 and the external cooling device 20 to facilitate heat transfer from the third heat pipe portion 1264 to the external cooling device 20.

In some examples, the lengths of the corresponding third heat pipe portions 1264 of the two heat pipes 126 can be the same, but different in width or different both in length and width, as long as the corresponding heat dissipation efficiency requirements can be met or sufficient contact with the external cooling device can be ensured.

FIG. 3A shows a schematic diagram of a cooling configuration for memory module 12 according to a third example of the present disclosure. FIG. 3B shows a schematic diagram of the coupling of the cooling configuration for memory module 12 to an external cooling device 20 according to the third example of the present disclosure. In the illustrated example of FIG. 3A, the construction of the heat pipe 126 of the cooling configuration for memory module 12 is substantially the same as the construction of the heat pipe 126 in the example of FIG. 1, and the only difference lies in the geometry of the second main heat dissipation surface 1268 of the corresponding third heat pipe portion 1264 of the heat pipe 126. As described above, in the example of FIG. 1, the second main heat dissipation surface 1268 of the corresponding third heat pipe portion 1264 of the two heat pipes 126 is also structured as a flat surface, that is, a plane perpendicular to both the longitudinal direction and the thickness direction of the memory board 14. However, as shown in the illustrated example of FIG. 3B, the coupling of the cooling configuration for memory module 12 to an external cooling device 20 according to the third example of the present disclosure is shown. Generally, to increase (e.g., maximize) the heat dissipation capacity of the heat pipe 126, the second main heat dissipation surface 1268 of the third heat pipe portion 1264 contacts the external cooling device 20 as much as possible. In this case, to expand the contact area between the second main heat dissipation surface 1268 of the corresponding third heat pipe portion 1264 of the heat pipe 126 and the external cooling device 20, the second surface 1268 of the corresponding third heat pipe portion 1264 of the heat pipe 126 is designed to be a non-planar shape. In some examples, the non-planar shape includes any convex three-dimensional shape, for example semi-cylindrical, spherical, semi-elliptical, triangular, etc. (because the thickness of the heat pipe 126 itself is very small, the second surface is not suitable for being made into a concave shape). Accordingly, a corresponding receiving surface 21 that contacts the second main heat dissipation surface 1268 can be provided in the external cooling device 20 to expand the contact area between the second surface 1268 of the corresponding third heat pipe portion 1264 of the heat pipe 126 and the external cooling device 20. In the illustrated example of FIG. 3A, the second surface 1268 of the corresponding third heat pipe portion 1264 of the heat pipe 126 is designed to be semi-cylindrical (semi-circular), so that the area of the second surface is enlarged. Accordingly, a corresponding semi-cylindrical receiving surface 21 is provided in the external cooling device 20 in contact with the second surface 1268, so that the second surface 1268 of the corresponding third heat pipe portion 1264 of the heat pipe 126 can be accommodated in the corresponding semi-cylindrical receiving surface 21 of the external cooling device 20. In addition to facilitating the cooling of the memory module 10 or the memory board 14, this structure also helps to position and disassemble the memory module 10 (including the cooling configuration for memory module 12).

FIG. 3C is a schematic diagram of an alternate elastic structure 210. In the illustrated example of FIG. 3C, the elastic structure 210 is a coiled spring. FIG. 3D is a schematic diagram of an alternate elastic structure 210. In the illustrated example of FIG. 3D, the elastic structure 210 is a clip.

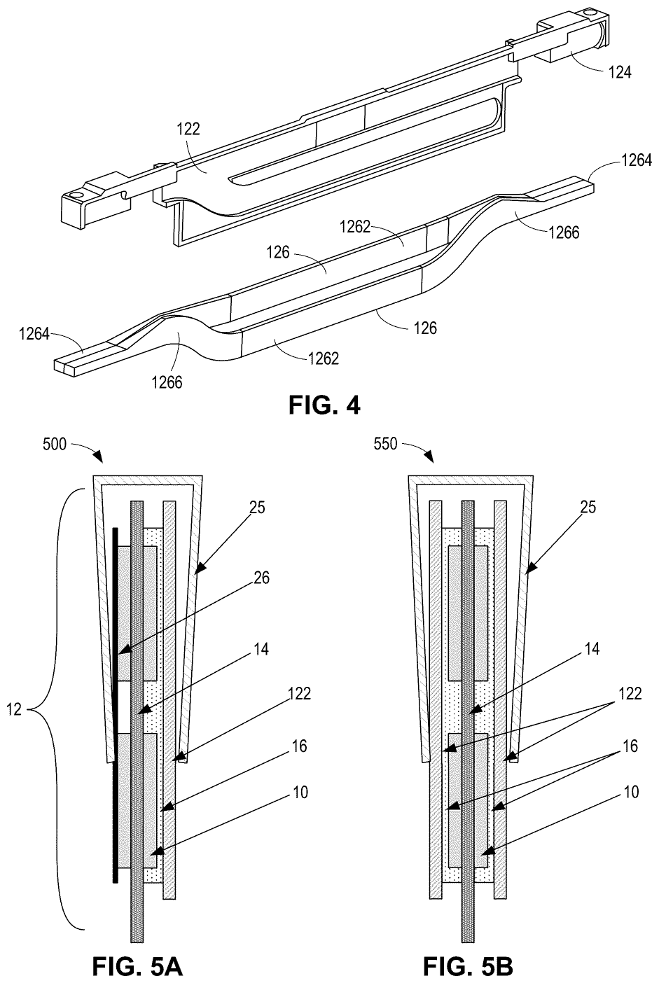

FIG. 4 shows a schematic diagram of a cooling configuration for memory module 12 according to a fourth example of the present disclosure. In the illustrated example of FIG. 4, the cooling configuration for memory module 12 is substantially the same as that in any of the previous examples, and the only difference lies in the structure of the corresponding third heat pipe portion 1264 of the heat pipe 126. As shown in the illustrated example of FIG. 4, in the fourth example each cooling configuration for memory module 12 still includes two heat pipes 126. However, each heat pipe 126 includes one first heat pipe portion 1262, two second transition portions 1266, and two third heat pipe portions 1264. In other words, in the fourth example, each heat pipe 126 includes a third heat pipe portion 1264 at both ends (or on both sides of the heat sink) in the longitudinal direction of the memory board 14, and the two corresponding third heat pipe portions 1264 of the two heat pipes 126 on the same side of the memory board 14 are arranged in parallel and in contact with each other in a shape-matched manner (e.g., arranged in parallel along the thickness direction of the memory board 14). As shown in the illustrated example of FIG. 4, in this example, two corresponding third heat pipe portions 1264 of two heat pipes 126 on the same side of the heat sink 122 of the memory board 14 in the longitudinal direction are arranged in parallel and in contact with each other in a shape-fitting manner along the thickness direction of the memory board 14 to further optimize the compactness of the entire cooling configuration for memory module 12. In the illustrated example of FIG. 4, the third heat pipe portions 1264 include an orthogonal profile that is generally an elongated rectangle. In the illustrated example of FIG. 4, for limited space and a determined number of memory modules 10 to be installed, it can be considered that for each heat pipe 126, the width of each third heat pipe portion 1264 thereof is reduced and the total width of the two corresponding third heat pipe portions 1264 of the two heat pipes 126 on the same side of the heat sink 122 of the memory board 14 in the longitudinal direction is within a specified range.

As an example, in the illustrated example of FIG. 4, the shapes of the main heat dissipation surfaces of the two third heat pipe portions 1264 of the two heat pipes 126 are structured to be rectangular so that the corresponding third heat pipe portions 1264 of the two heat pipes 126 on the same side in the longitudinal direction of the memory board 14 can be arranged in parallel and in contact with each other in a shape-matched manner.

In some examples, the width of two corresponding third heat pipe portions 1264 that are arranged in parallel and contact with each other in a shape-matched manner on the same side of the heat sink 122 of the memory board 14 in the longitudinal direction are roughly equivalent to the width of the corresponding third heat pipe portions 1264 in the first to third examples, in which there is only one third heat pipe portion 1264 on either side of the heat sink 122 of the memory board 14 in the longitudinal direction.

Although examples in the drawings of the present disclosure, the cooling configuration for memory module 12 each includes two heat pipes 126, this is only for purposes of example and explanation, and not limited. In some examples, each cooling configuration for memory module 12 includes only one heat pipe 126 or more than two heat pipes 126 without departing from the scope of the present disclosure. As an example, for the case where each cooling configuration for memory module 12 includes only one heat pipe, the heat pipe 126 will include one first heat pipe portion 1262, two second transition portions 1266, and two third heat pipe portions 1264, in which the two second transition portions 1266 and the two third heat pipe portions 1264 in the heat pipe 126 are both extended in opposite directions in the longitudinal direction away from the memory board 14 or the heat sink 122 (if present). In some examples, to ensure sufficient contact area with the memory board 14 or the heat sink 122 (if present), the first heat pipe portion 1264 can be structured to have a larger (e.g., wider) width dimension, for example, occupying one-half or more of the width of the memory board 14 or the heat sink 122 (if present). Further, for the case of more than two heat pipes 126, one or more additional 3D heat pipes can be further added based on the fourth example, or more than two heat pipes having only one third heat pipe portion 1264 can be modified in accordance with the fourth example. That is, two or more 3D heat pipes having only one third heat pipe portion 1264 leads to the fact that the corresponding third heat pipe portions 1264 arranged in parallel and in contact with each other in a shape-matched manner on one side of the heat sink 122 or the memory board 14 will form a larger heat pipe portion.

Although in the above-mentioned first to fourth examples the cooling configuration for memory module 12 is only arranged on one side of the memory board 14, examples disclosed herein permit the possibility that the cooling configuration for memory module 12 can be respectively arranged on both sides of the memory board 14 or the memory module 10 without departing from the scope of the present disclosure.

It should be understood that the cooling configuration for memory module 12 with different structures as described in the above different examples can be used separately or in any technically possible combination without departing from the scope of the present disclosure, unless such combination is explicitly excluded or causes technical contradictions.

Although the present disclosure is described in detail above with reference to specific drawings, these descriptions are provided for purposes of example and explanation, and various modifications may be made without departing from the teachings of the present disclosure and without departing from the scope of the present disclosure. In some examples, the size of the heat pipe 126 may be adjusted based on the size of the memory module mainboard and the memory module 10, the size of the corresponding third heat pipe portion 1264 of the heat pipe 126 may be adjusted based on the heat dissipation requirements and the specifications of the external cooling device, the shape of the corresponding second transition portion of the heat pipe 126 may be adjusted based on the manufacturing process and may or may not include a curved plane, the shape of the heat sink may be adjusted based on the shape of the memory board 14, etc.

In the first to fourth examples of the present disclosure, considering the 0.3-inch mounting pitch of known memory modules on the memory module mainboard (the mounting pitch represents the distance between two adjacent memory modules mounted on the memory module mainboard), examples disclosed herein permit the width of the third heat pipe portion 1264 of each heat pipe to be 7 mm. For the fourth example, the width of each third heat pipe portion 1264 of each heat pipe may be 3.5 mm respectively and therefore the total width of the two third heat pipe portions arranged in parallel and in contact with each other is 7 mm. Examples disclosed herein enable the section of different widths of the third heat pipe portions according to the specifications, properties, heat dissipation requirements, etc. of different heat pipes.

In some examples disclosed herein, the first to fourth examples include lengths and widths of the corresponding first heat pipe portions 1262 of the two heat pipes to be the same. In some examples, at least one of the lengths or widths of the corresponding first heat pipe portions 1262 of the two heat pipes can be different from each other.

In some examples disclosed herein, the first to fourth examples include the corresponding first heat pipe portions 1262 of the two heat pipes 126 to be arranged parallel to each other in the heat sink. In some examples the first heat pipe portions 1262 are arranged non-parallel to each other.

FIG. 5A shows a reference schematic diagram of a clip assembly 500 having a TIM 16 in a cooling device 12 according to the present disclosure. The illustrated example of FIG. 5A includes the clip 25, the memory board 14, memory components 10, and at least one insulator 26. As mentioned above, to ensure improved contact between the surface components of the memory board 14 and the heat sink 122 or the heat pipe 126 itself to promote heat dissipation, at least one layer of the TIM 16 is provided between the heat sink 122 or the heat pipe 126 and the memory board 14 (see right side of FIG. 5A). In some examples, TIMs 16 may be implemented in the form of sheets and inserted between the memory board 14 and the corresponding heat sink 122 on both sides of the cooling device 12, as shown as a clip assembly 550 in FIG. 5B. In such examples of assembly of the memory board 14 and the cooling configuration for memory module 12, the TIM 16 is applied or provided in a fixed area on the side of the cooling configuration for memory module 12 facing the memory board 14. However, for some example TIM arrangements, the thickness of the TIM may be uneven or too thick, thereby causing unnecessary space occupation. On the other hand, some example TIM arrangements cannot ensure complete coverage to each surface component, and there may be areas on the side surfaces of the surface components that cannot be directly covered by the TIM. In such circumstances, cooling the memory board 14 is relatively less effective, especially with regard to efforts to cool the surface components on the side of the memory board 14 facing the TIM.

In the illustrated example of FIGS. 5A and 5B, a cured TIM 16 is pre-coated and attached to the memory board 14, which is arranged between the cooling configuration for memory module 12 and the memory board 14. In the illustrated example of FIGS. 5A and 5B, the TIM 16 is in fluid before being cured and is applied to at least one side of the memory board 14 and then cured to be pre-coated and attached to the memory board 14. In some examples, curing and pre-coating covers all surface components of the memory board 14 as much as possible. The above-mentioned method of pre-coating and attaching at least one side of the memory board 14 with the TIM 16 in fluid is, for example, dipping or overmolding. Such dipping or overmolding achieves coating by curing the fluid TIM on the memory board 14 in a mold. In some examples, the sufficient contact between the surface components of the memory board and the corresponding TIM is ensured as much as possible to enable heat transfer and flatness. In some examples, such cured TIM also ensures certain elastic properties, thereby providing additional protection for surface components. In some examples, the curing of the cured liquid TIM is reversible or its removal is easy. In some examples the cured TIM can be cured with the help of a liquid two-phase epoxy so as to completely cover the surface components of the memory board with the cured TIM.

Although not described separately and in detail in the examples of the present disclosure, examples disclosed herein relate to a memory module cooling system, which includes: a cooling device 12, which is attached to the memory board via TIM 16 as described in any one of the above examples or combinations thereof; and an external cooling device (e.g., the external cooling device 20 of FIG. 2B). The external cooling device 20 may be is structured to be arranged on the outer surface of the memory module mainboard receiving the memory module 10 so that when the memory module 10 provided with the cooling configuration for memory module 12 is attached to the memory module mainboard, at least one main heat dissipation surface of the third heat pipe portion 1264 of the heat pipe 126 of the cooling device 12 directly or via TIM contacts the external cooling device to promote the dissipation of the heat carried by the heat pipe 126. In some examples, the above-mentioned external cooling device 20 can be selected as any possible cooling device such as an external liquid cooling device without departing from the scope of the present disclosure.

While example memory module cooling system disclosed herein includes heat sinks, these heat sinks are not necessary and it is conceivable that the memory module cooling system disclosed herein may not include heat sinks and the heat pipes may be directly attached to at least one side of the memory board. In this case, any appropriate technology may be used to ensure that the heat pipes and the memory board remain relatively fixed so as to be able to dissipate the heat from the memory board.

In some examples, the respective first heat pipe portions of the two heat pipes are arranged parallel to each other when attached to the memory board. In some examples, the respective first heat pipe portions of the two heat pipes are structured to cover the surface of the side of the memory board as much as possible.

In some examples, and in the absence of a heat sink, the main heat dissipation surface of the first heat pipe portion of the heat pipe is substantially parallel to at least one side of the board surface of the memory board, and is attached to the at least one side of the memory board. In this case, the possible second transition portion and the third heat pipe portion of the heat pipe both extend away from the memory board without contacting the memory board. For the third heat pipe portion that is substantially orthogonal to the main heat dissipation surface of the first heat pipe portion, in some examples the third heat pipe portion has a first main heat dissipation surface along the transverse direction of the memory board, which corresponds to the side away from the electrical terminal pins of the memory board, and a second main heat dissipation surface, which is opposite to the first main heat dissipation surface and closer to the electrical terminal pins of the memory board. In some examples, the first surface and the second surface of the third heat pipe portion of the heat pipe (or at least one of them) can be structured to contact an external cooling device to achieve the dissipation of the heat received by the first heat pipe portion of the heat pipe.

In some examples, and in the absence of a heat sink, each heat pipe includes one first heat pipe portion, two second transition portions, and two third heat pipe portions. In this case, each heat pipe includes one third heat pipe portion at either ends (or on either sides of the memory board) in the longitudinal direction and the two corresponding third heat pipe portions on the same side of the memory board of the two heat pipes are arranged in parallel contact with each other in a shape-matched manner (e.g., arranged in parallel along the thickness direction of the memory board). Although some examples disclosed herein include two heat pipes, using only one heat pipe or more than two heat pipes may be realized without limitation. In some examples using only one heat pipe, it can be considered that the width of the first heat pipe portion of the one heat pipe should be large enough to cover at least one side of the memory board as much as possible. In some examples including more than two heat pipes, it can be considered that the corresponding first heat pipe portions of the more than two heat pipes can be and are arranged on at least one side of the memory board to cover at least one side of the memory board as much as possible to promote heat dissipation.

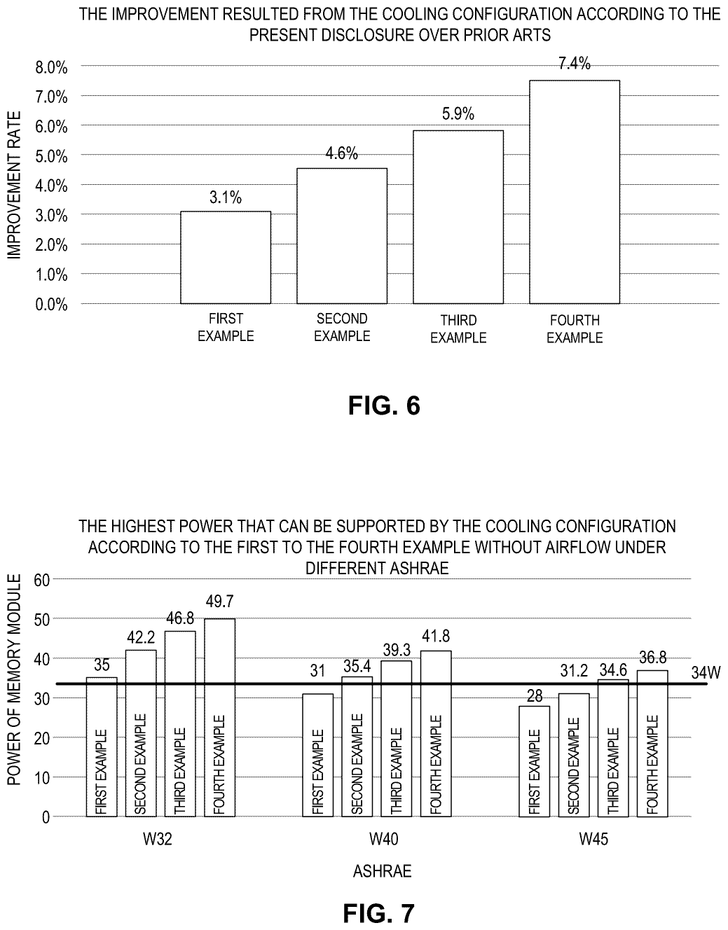

FIG. 6 is a table diagram showing the improvement in heat dissipation capability achieved by the cooling configuration for memory modules according to various examples disclosed herein compared to known cooling configuration techniques.

In the illustrated example of FIG. 6, the improvement obtained by the first to fourth examples of the present disclosure under the same environment (e.g., for memory modules with the same power installed on the same memory module motherboard) compared with known techniques. In the illustrated example of FIG. 6, the cooling configuration for memory module of the fourth example achieves the greatest improvement in heat dissipation capacity and has the strongest heat dissipation capacity.

FIG. 7 is a table diagram showing different maximum powers that the cooling configuration for memory modules of the first to fourth examples of the present disclosure can handle for different thermal classification standards (e.g., the American Society of Heating, Refrigerating and Air-Conditioning Engineers (ASHRAE) classification standard W32, W40 and W45) without airflow for the memory modules that have been transferred to the memory cooling system. The example W32 classification standard in FIG. 7 indicates that the liquid injection temperature of the external cooling device (water cooling) is 32 degrees Celsius, and the other classifications are similar. In the illustrated example of FIG. 6, because the fourth example has the relatively strongest heat dissipation capacity, it can achieve higher power for different memory modules, which helps to expand the types of memory modules that can be used compared to known techniques and/or structures, and realize the wide disclosure of the cooling configuration for memory module.

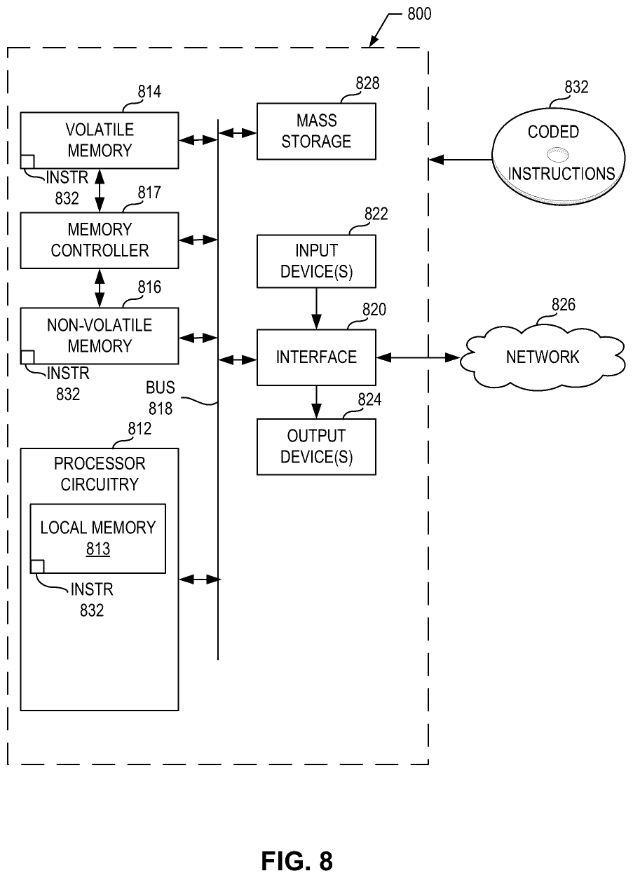

FIG. 8 is a block diagram of an example programmable circuitry platform 800 within which examples disclosed herein may reside and/or otherwise operate. The programmable circuitry platform 800 can be, for example, a server, a personal computer, a workstation, a self-learning machine (e.g., a neural network), a mobile device (e.g., a cell phone, a smart phone, a tablet such as an iPad™), an Internet appliance, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 800 of the illustrated example includes programmable circuitry 812. The programmable circuitry 812 of the illustrated example is hardware. For example, the programmable circuitry 812 can be implemented by one or more integrated circuits, logic circuits, FPGAs, microprocessors, CPUs, GPUs, VPUs, DSPs, and/or microcontrollers from any desired family or manufacturer. The programmable circuitry 812 may be implemented by one or more semiconductor based (e.g., silicon based) devices.

The programmable circuitry 812 of the illustrated example includes a local memory 813 (e.g., a cache, registers, etc.). The programmable circuitry 812 of the illustrated example is in communication with main memory 814, 816, which includes a volatile memory 814 and a non-volatile memory 816, by a bus 818. The volatile memory 814 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 816 may be implemented by flash memory and/or any other desired type of memory device. In some examples disclosed herein, one or more of the local memory 813, the non-volatile memory 816 and/or the volatile memory 1014 implement one or more variations of the example cooling device 12. Access to the main memory 814, 816 of the illustrated example is controlled by a memory controller 817. In some examples, the memory controller 817 may be implemented by one or more integrated circuits, logic circuits, microcontrollers from any desired family or manufacturer, or any other type of circuitry to manage the flow of data going to and from the main memory 814, 816.

The programmable circuitry platform 800 of the illustrated example also includes interface circuitry 820. The interface circuitry 820 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 822 are connected to the interface circuitry 820. The input device(s) 822 permit(s) a user (e.g., a human user, a machine user, etc.) to enter data and/or commands into the programmable circuitry 812. The input device(s) 822 can be implemented by, for example, an audio sensor, a microphone, a camera (still or video), a keyboard, a button, a mouse, a touchscreen, a trackpad, a trackball, an isopoint device, and/or a voice recognition system.

One or more output devices 824 are also connected to the interface circuitry 820 of the illustrated example. The output device(s) 824 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 820 of the illustrated example, thus, typically includes a graphics driver card, a graphics driver chip, and/or graphics processor circuitry such as a GPU.

The interface circuitry 820 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 826. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 800 of the illustrated example also includes one or more mass storage discs or devices 828 to store firmware, software, and/or data. Examples of such mass storage discs or devices 828 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 832, which may be implemented by machine readable instructions, may be stored in the mass storage device 828, in the volatile memory 814, in the non-volatile memory 816, and/or on at least one non-transitory computer readable storage medium such as a CD or DVD which may be removable.

The above examples described in this disclosure are exemplary and non-restrictive. Various modifications can be made to the above examples according to the disclosure without departing from the scope of this disclosure.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

From the foregoing, it will be appreciated that example systems, apparatus, articles of manufacture, and methods have been disclosed that improve thermal management of memory devices. Examples disclosed herein facilitate a change of orientation between memory devices that generate heat, and cooling devices to sink the generated heat. In some examples, the change of orientation permits a substantially vertical thermal flow path to take advantage of directional thermal heat evacuation in an upward direction. Such improved thermal management reduces an energy consumption that would otherwise be applied to cooling effort(s). Disclosed systems and apparatus are accordingly directed to one or more improvement(s) in the operation of a machine such as a computer or other electronic and/or mechanical device.

Example cooling configuration devices are disclosed herein. Further examples and combinations thereof include the following:

Example 1 includes a cooling device comprising a heat sink including a longitudinal length having a left end, a right end, and a first planar orientation, a transverse height having a top, a bottom, and a second planar orientation orthogonal to the first planar orientation, and an inner side and an outer side, the outer side including at least one channel having the second planar orientation, and a first heat pipe including a first heat pipe portion having a left end, a right end, and the second planar orientation, the first heat pipe portion seated into the at least one channel, a heat pipe transition portion coupled to the left end of the first heat pipe portion, the transition portion including a first end having the second planar orientation and a second end having the first planar orientation, and a heat dissipation portion coupled to the second end of the heat pipe transition portion.

Example 2 includes the cooling device as defined in example 1, further including a first heat sink block coupled to the left end of the heat sink, the first heat sink block having a top side and a bottom side.

Example 3 includes the cooling device as defined in any one or more of examples 1-2, wherein the first heat sink block includes a block receiving groove on the bottom side.

Example 4 includes the cooling device as defined in any one or more of examples 1-3, wherein the bottom side of the first heat sink block thermally connects to the heat dissipation portion of the first heat pipe.

Example 5 includes the cooling device as defined in any one or more of examples 1-4, further including an elastic structure coupled to the top side of the first heat sink block.

Example 6 includes the cooling device as defined in any one or more of examples 1-5, wherein the elastic structure is at least one of a clip or a spring.

Example 7 includes the cooling device as defined in any one or more of examples 1-6, wherein the first heat pipe portion includes an orthogonal profile along the longitudinal length of the heat sink.

Example 8 includes the cooling device as defined in any one or more of examples 1-7, wherein the heat dissipation portion of the first heat pipe includes a rectangular profile having a length extending beyond the longitudinal length of the heat sink.

Example 9 includes the cooling device as defined in any one or more of examples 1-8, wherein the heat dissipation portion of the first heat pipe thermally connects between the heat sink and a cold plate.

Example 10 includes the cooling device as defined in any one or more of examples 1-9, further including an elastic structure coupled to the heat dissipation portion, and a clamp, the elastic structure to provide a contact force between the clamp and the cold plate.

Example 11 includes the cooling device as defined in any one or more of examples 1-10, wherein the elastic structure is to provide the contact force when the clamp is in a closed position.

Example 12 includes the cooling device as defined in any one or more of examples 1-10, wherein the elastic structure is at least one of a clip or a spring.

Example 13 includes the cooling device as defined in any one or more of examples 1-12, wherein the heat dissipation portion of the first heat pipe includes a cylindrical profile having a length extending beyond the longitudinal length of the heat sink.

Example 14 includes the cooling device as defined in any one or more of examples 1-13, wherein the cylindrical profile thermally connects to a semi-circular profile of a cold plate.

Example 15 includes the cooling device as defined in any one or more of examples 1-14, further including a thermal interface material between the heat sink and a memory board.

Example 16 includes the cooling device as defined in any one or more of examples 1-15, further including a second heat pipe, the second heat pipe including a first heat pipe portion having a left end, a right end, and the second planar orientation, the first heat pipe portion seated into a second channel of the heat sink, a heat pipe transition portion coupled to the right end of the first heat pipe portion, the transition portion including a first end having the second planar orientation and a second end having the first planar orientation, and a heat dissipation portion coupled to the second end of the heat pipe transition portion, the heat dissipation portion of the second heat pipe extending the longitudinal length opposite to the heat dissipation portion of the first heat pipe.

Example 17 includes a heat pipe comprising a longitudinal portion including a rectangular cross section, the longitudinal portion having a first length along a first plane orientation, the first length between a first end and a second end of the longitudinal portion, and a transition portion including a first end coupled to the longitudinal portion having the first plane orientation, and a second end having a second plane orientation orthogonal to the first plane orientation.

Example 18 includes the heat pipe as defined in example 17, wherein the second end of the transition portion includes a heat dissipation portion having the second plane orientation.

Example 19 includes the heat pipe as defined in any one or more of examples 17-18, wherein the heat dissipation portion includes a second length extending parallel to the first length of the first longitudinal portion.

Example 20 includes the heat pipe as defined in any one or more of examples 17-19, wherein the second length includes at least one of a rectangular cross section or a circular cross section.

It is noted that this patent claims priority from Chinese Patent Application Number 202420765812.4, which was filed on Apr. 15, 2024, and is hereby incorporated by reference in its entirety.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A cooling device comprising:
a heat sink including:
a longitudinal length having a left end, a right end, and a first planar orientation;
a transverse height having a top, a bottom, and a second planar orientation orthogonal to the first planar orientation; and
an inner side and an outer side, the outer side including at least one channel having the second planar orientation; and
a first heat pipe including:
a first heat pipe portion having a left end, a right end, and the second planar orientation, the first heat pipe portion seated into the at least one channel;
a heat pipe transition portion coupled to the left end of the first heat pipe portion, the transition portion including a first end having the second planar orientation and a second end having the first planar orientation; and
a heat dissipation portion coupled to the second end of the heat pipe transition portion.

2. The cooling device as defined in claim 1, further including a first heat sink block coupled to the left end of the heat sink, the first heat sink block having a top side and a bottom side.

3. The cooling device as defined in claim 2, wherein the first heat sink block includes a block receiving groove on the bottom side.

4. The cooling device as defined in claim 3, wherein the bottom side of the first heat sink block thermally connects to the heat dissipation portion of the first heat pipe.

5. The cooling device as defined in claim 2, further including an elastic structure coupled to the top side of the first heat sink block.

6. The cooling device as defined in claim 5, wherein the elastic structure is at least one of a clip or a spring.

7. The cooling device as defined in claim 1, wherein the first heat pipe portion includes an orthogonal profile along the longitudinal length of the heat sink.

8. The cooling device as defined in claim 1, wherein the heat dissipation portion of the first heat pipe includes a rectangular profile having a length extending beyond the longitudinal length of the heat sink.

9. The cooling device as defined in claim 8, wherein the heat dissipation portion of the first heat pipe thermally connects between the heat sink and a cold plate.

10. The cooling device as defined in claim 9, further including:
an elastic structure coupled to the heat dissipation portion; and
a clamp, the elastic structure to provide a contact force between the clamp and the cold plate.

11. The cooling device as defined in claim 10, wherein the elastic structure is to provide the contact force when the clamp is in a closed position.

12. The cooling device as defined in claim 10, wherein the elastic structure is at least one of a clip or a spring.

13. The cooling device as defined in claim 1, wherein the heat dissipation portion of the first heat pipe includes a cylindrical profile having a length extending beyond the longitudinal length of the heat sink.

14. The cooling device as defined in claim 13, wherein the cylindrical profile thermally connects to a semi-circular profile of a cold plate.

15. The cooling device as defined in claim 1, further including a thermal interface material between the heat sink and a memory board.

16. The cooling device as defined in claim 1, further including a second heat pipe, the second heat pipe including:
a first heat pipe portion having a left end, a right end, and the second planar orientation, the first heat pipe portion seated into a second channel of the heat sink;
a heat pipe transition portion coupled to the right end of the first heat pipe portion, the transition portion including a first end having the second planar orientation and a second end having the first planar orientation; and
a heat dissipation portion coupled to the second end of the heat pipe transition portion, the heat dissipation portion of the second heat pipe extending the longitudinal length opposite to the heat dissipation portion of the first heat pipe.

17. A heat pipe comprising:
a longitudinal portion including a rectangular cross section, the longitudinal portion having a first length along a first plane orientation, the first length between a first end and a second end of the longitudinal portion; and
a transition portion including:
a first end coupled to the longitudinal portion having the first plane orientation; and
a second end having a second plane orientation orthogonal to the first plane orientation.

18. The heat pipe as defined in claim 17, wherein the second end of the transition portion includes a heat dissipation portion having the second plane orientation.

19. The heat pipe as defined in claim 18, wherein the heat dissipation portion includes a second length extending parallel to the first length of the first longitudinal portion.

20. The heat pipe as defined in claim 19, wherein the second length includes at least one of a rectangular cross section or a circular cross section.
